(19) United States
(12) Patent Application Publication
(10) Pub. No.: US 2010/0279469 A1
(43) Pub. Date: Nov. 4, 2010

(54) Low-Voiding Die Attach Film, Semiconductor Package, and Processes for Making and Using Same

(76) Inventor: Hwail Jin, Cumming, GA (US)

Correspondence Address: Henkel Corporation, 10 Finderne Avenue, Suite B, Bridgewater, NJ, 08807, US

(21) Appl. No.: 12/777,388

(22) Filed: May 11, 2010

Related U.S. Application Data
(63) Continuation of application No. PCT/US2007/085278, filed on Nov. 20, 2007.

(51) Int. Cl. H01L 21/56; B32B 38/10; C08L 63/00; C08L 83/04; C08L 39/04

(52) U.S. Cl. 438/113; 156/235; 525/119; 525/476; 525/205; 257/E21.502

(57) ABSTRACT

This invention is a low-voiding adhesive film prepared from a composition. The composition comprises a toughening polymer, a curable resin, a curing agent for the curable resin, a void reduction compound, and a curing agent for the void reduction compound. The void reduction compound has at least two Si—O moieties contiguous with each other and at least one reactive functionality. Additional embodiments of this invention are described, including a process for producing the low-voiding die attach film, a method for reducing voids in a semiconductor package using the film of this invention, and a semiconductor package assembled with the film of this invention.

### CROSS-REFERENCE TO RELATED APPLICATION

This application is a continuation of International Application No. PCT/US2007/085278 filed Nov. 20, 2007, the contents of which is incorporated herein by reference.

### FIELD OF THE INVENTION

This invention relates to adhesive films that exhibit very low voiding characteristics while maintaining flow and wet-out performance and to processes for making those films. In particular, these films are useful for attaching dies in semiconductor packages.

### BACKGROUND OF THE INVENTION

Adhesive films are often used for attaching articles to substrates. In one application, adhesive films are used to attach semiconductor dies to substrates in semiconductor packages. Generally, these films are compositions that are applied to a carrier and then B-staged to partially cure or dry the composition into a film form. The film is then applied to an article, such as, a semiconductor wafer or die, or to a substrate, and used to bond one item to another. These types of films can be advantageous when it is desirable to have limited, or very controlled, flow of the adhesive during subsequent processing steps. Unfortunately, they also have the disadvantage of developing air or moisture voids from air or moisture present in the substrate.

The voids then expand during downstream curing of the adhesive, or during other thermal operations, such as wirebonding a silicon die to a leadframe substrate, and their presence can result in device failure. One remedy for the problem of voids is to raise the molecular weight of the adhesive. This leads to an increased inherent strength of the adhesive, which resists the force created by the expansion of the air and moisture. However, often the increased molecular weight of the adhesive results in a film that does not flow enough to wet-out the surfaces to which it is applied, resulting in an unsatisfactory bond. Thus, there is a need for an adhesive film that gives good flow and wet-out without developing voids in the bondline during curing and other thermal operations, such as, wirebonding.

### SUMMARY OF THE INVENTION

This invention is a low-voiding adhesive film prepared from a composition comprising a toughening polymer, a curable resin, a curing agent for the curable resin, a void reduction compound having at least two silicon-to-oxygen (Si—O) moieties contiguous with each other and at least one reactive functionality, and a curing agent for the void reduction compound.

In another embodiment this invention is a process for producing a low-voiding adhesive film. The film is produced by (i) providing a composition comprising a toughening polymer, a curable resin, a curing agent for the curable resin, a void reduction compound having at least two Si—O moieties contiguous with each other and at least one reactive functionality, and a curing agent for the void reduction compound; (ii) applying the composition to a carrier; and (iii) B-staging the composition, thereby producing an adhesive film.

In another embodiment this invention is a method for reducing the voids in a cured adhesive film. In particular, this invention is a method for reducing the voids in a semiconductor package. The method comprises (i) providing a composition comprising a toughening polymer, a curable resin, a curing agent for the curable resin, a void reduction compound having at least two Si—O moieties contiguous with each other and at least one reactive functionality, and a curing agent for the void reduction compound; (ii) applying the composition to a carrier; (iii) B-staging the composition thereby producing an adhesive film on the carrier (hereinafter, adhesive film plus carrier); (iv) contacting the adhesive side of the adhesive film plus carrier to an article or its substrate; (v) removing the carrier to expose the adhesive film; (vi) contacting the article, if the adhesive is applied to the substrate for the article, or contacting the substrate, if the adhesive is applied to the article, to the exposed adhesive film so that the adhesive film is disposed between the article and its substrate; and (vii) subjecting the film to at least one thermal operation. In a particular embodiment, step (iv) comprises contacting the adhesive side of the adhesive film to a semiconductor die or its substrate.

For the purposes of clarity, in step (iv) the adhesive film can be applied either to the article or its substrate. Thus, after the carrier is removed in step (v), if the adhesive film is applied to the article in step (vi), the substrate will be contacted to the exposed side of the adhesive film; if applied to the substrate, the article will be contacted to the exposed side of the adhesive film.

In another embodiment, this invention is a semiconductor package prepared by A semiconductor package prepared by (i) providing a composition comprising a toughening polymer, a curable resin, a curing agent for the curable resin, a void reduction compound having at least two Si—O moieties contiguous with each other and at least one reactive functionality, and a curing agent for the void reduction compound; (ii) applying the composition to a carrier; (iii) B-staging the composition, thereby producing an adhesive film plus carrier; (iv) contacting the adhesive side of the adhesive film plus carrier to a dicing tape; (v) laminating the adhesive film to the dicing tape, thereby producing a bundled wafer backside lamination (BWBL) film; (vi) removing the carrier, contacting the exposed adhesive side of the BWBL film to a semiconductor wafer and laminating the BWBL to the semiconductor wafer so that the adhesive film is disposed between the semiconductor wafer and the dicing tape; (vii) dicing the wafer and adhesive into individual semiconductor dies with adhesive; (viii) removing a die with the adhesive film attached from the dicing tape; (ix) contacting the adhesive film side of the die with adhesive film attached to a substrate so that the adhesive film is disposed between the semiconductor die and the substrate to form an assembly; and (x) subjecting the assembly to at least one thermal operation.

### BRIEF DESCRIPTION OF THE FIGURES

The present invention can be more fully understood by reading the following detailed description with reference to the accompanying drawings, wherein:

FIG. 1 is a schematic representation of a bundled wafer backside lamination (BWBL) film before and after lamination to a semiconductor wafer, and FIG. 2 is a schematic representation of a BWBL assembly process.

### DEFINITIONS

The term “alkyl” refers to a branched or un-branched saturated hydrocarbon group of 1 to 24 carbon atoms, such as methyl (“Me”), ethyl (“Et”), n-propyl, isopropyl, n-butyl, isobutyl, t-butyl, octyl, decyl, and the like.

The term “effective amount” of a compound, product, or composition means a sufficient amount of the compound, product or composition to provide the desired results. The exact amount required will vary depending on the particular compound, product, or composition used, its mode of administration, and the like. Thus, it is not always possible to specify an exact amount; however, an effective amount may be determined by one of ordinary skill in the art using only routine experimentation.

The term “suitable” means the compounds, products, or compositions as provided can be used for the stated purpose to provide the stated result. Suitability for the stated purpose may be determined by one of ordinary skill in the art using only routine experimentation.

The term “to laminate” (and its variants) means to bond at least two types of materials together, typically with heat and pressure.

The term “B-staging” (and its variants) is used to refer to the processing of a material by heat or irradiation so that if the material is dissolved or dispersed in a solvent, the solvent is evaporated off with or without partial curing of the material, or if the material is neat with no solvent, the material is partially cured to a tacky or more hardened state. If the material is a flow-able adhesive, B-staging will provide extremely low flow without fully curing, such that additional curing may be performed after the adhesive is used to join one article to another. The reduction in flow may be accomplished by evaporation of a solvent, partial advancement or curing of a resin or polymer, or both.

The term “curing agent” is used to refer to any material or combination of materials that initiate, propagate, or accelerate cure of a composition, and includes, but is not limited to, accelerators, catalysts, initiators, and hardeners.

The term “carrier” is used to refer to any material that provides structural support to a film during fabrication and lamination processes. The carrier may be enmeshed in the film structure and remain part of the film throughout its fabrication and use. Alternatively, it may be removed from the film during a downstream operation after its structural support is no longer needed, as with a release liner that serves to hold the film during fabrication, but which is removed from the film after the film has been applied to a wafer or a substrate.

The term “thermal operation” means a step in the fabrication or manufacturing process of an article or semiconductor package at which heat is, or heat and pressure are, applied, to effect, for example, a cure, a bonding or soldering, or a reflow of solder or sintering of metal.

### DETAILED DESCRIPTION OF THE INVENTION

The low-voiding die attach film is produced from a composition that comprises a toughening polymer, a curable resin, a curing agent for the curable resin, a void reduction compound, and a curing agent for the void reduction compound. The void reduction compound is present in an effective amount. An effective amount will vary depending on the curable resin and toughening polymer system selected. In one embodiment the void reduction compound comprises 0.5-10 wt % of the adhesive formulation before B-staging, excluding solvent content. In another embodiment the void reduction compound comprises 3-6 wt % of the adhesive formulation before B-staging, excluding solvent content.

The void reduction compound has at least two Si—O moieties contiguous with each other and at least one reactive functionality. In one embodiment the reactive functionality is vinyl, epoxy, acrylate, methacrylate, or a combination of these. The void reduction compound is hydrophobic and non-hydrolyzable and may be a monomer, oligomer, copolymer, or polymer. Examples of suitable void reduction compounds include: acrylated siloxanes; epoxylated siloxanes; methacryloxypropyl-tris(trimethylsiloxy)silane; methacryloxypropyl T-structure siloxane; vinyl terminated polydimethylsiloxane; vinyl terminated (diphenylsiloxane)-dimethylsiloxane copolymer; epoxypropoxypropyl terminated polydimethylsiloxane; epoxypropoxypropyl terminated polydimethylsiloxane; and (vinylmethylsiloxane)-dimethylsiloxane copolymer, trimethylsiloxy terminated.

The curing agent for the void reduction compound is any material or combination of materials that will initiate, propagate, or accelerate cure of the void reduction compound and includes, but is not limited to, accelerators, catalysts, initiators, and hardeners. Suitable curing agents for void reduction compounds that have acrylate, vinyl, or methacrylate functionality include, but are not limited to, free radical initiators, including peroxides such as cumene hydroperoxide, and dicumyl peroxide. Suitable curing agents for void reduction compounds that have epoxy functionality include, but are not limited to, amines and aromatic diamines. The curing agent for the void reduction compound may be the same as the curing agent for the curable resin, or it may be different.

The composition contains at least one curable resin. The curable resin allows the composition to flow for coating and die attach, then cures to form a strong adhesive matrix for bonding. Curable resins suitable for use in the present invention include any that polymerize or cross-link to cure and that provide the desired rheology, modulus, coefficient of thermal expansion, and other properties required for the specific industrial application. The curable resin(s) may be polymers, oligomers, monomers, or a combination of these. Suitable curable resins include thermosets, elastomers, thermoset rubbers, or a combination of these.

Selection of a suitable curable resin is dependent upon the end use application, the article and substrate to be adhered. For semiconductor packaging end uses, the selection of curable resin will be dependent on semiconductor die type and size, type of substrate, package geometry, and manufacturing variables, such as, reflow temperatures and level of reliability required. The composition may or may not contain solvent, as deemed by the practitioner to be suitable for the particular film to be manufactured. Other components, typically used in adhesive compositions, may be added at the option of the practitioner; such other components include, but are not limited to, curing agents, fluxing agents, wetting agents, flow control agents, adhesion promoters, and air release agents. The adhesive composition may also contain filler, in which case the filler will be present in an amount up to 95 wt % of the composition before B-staging, excluding solvent content.

Curable resins used in the composition may be solid, liquid, or a combination of the two. Suitable curable resins include epoxies; acrylates or methacrylates; maleimides or bismalemides; vinyl ethers; polyimides; siliconized olefins; silicone resins; styrene resins; and cyanate ester resins. The curable resin will be present in an effective amount, typically between 5 and 99.5 wt % of the composition before B-staging. In one embodiment the curable resin is present in an amount ranging from 30 to 97 wt % of the composition before B-staging, excluding solvent content.

In one embodiment, the curable resin is a solid aromatic bismaleimide (BMI) resin. Suitable solid BMI resins are those having the structure

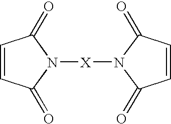

in which X is an aromatic group; exemplary aromatic groups include:

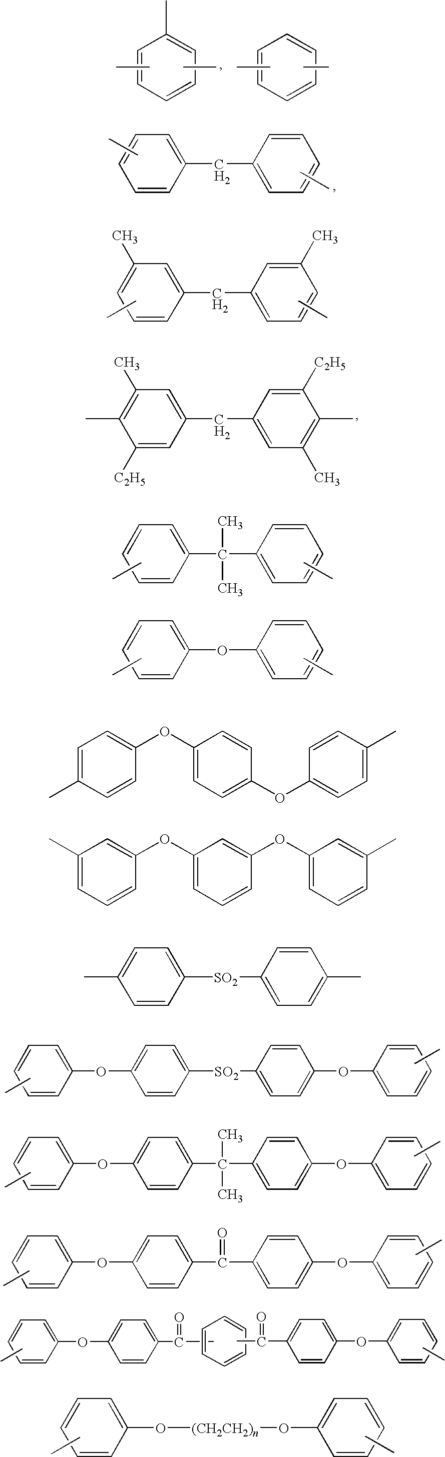

in which n is 1-3

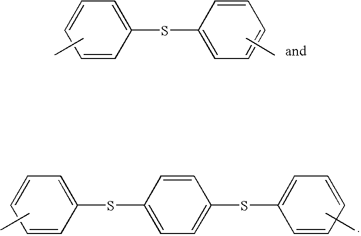

Bismaleimide resins having these X bridging groups are commercially available, and can be obtained, for example, from Sartomer (USA) or HOS-Technic GmbH (Austria).

In another embodiment, the curable resin is a maleimide resin having the generic structure

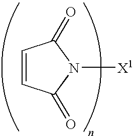

in which n is 1 to 3 and X¹ is an aliphatic or aromatic group. Exemplary X¹ entities include, poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. These types of resins are commercially available and can be obtained, for example, from National Starch and Chemical Company and Dainippon Ink and Chemical, Inc.

In one embodiment the curable resin of the composition is phenol novolac polyimide:

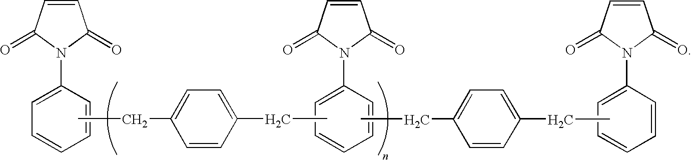

In another embodiment the curable resin of the composition is 3-maleimidopropionic acid/dimethyloctanol adduct.

In a further embodiment, the curable resin of the composition is a maleimide resin selected from the group consisting of

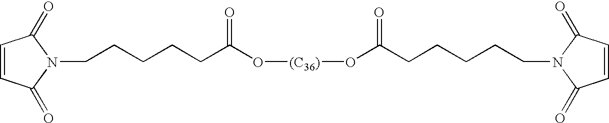

in which C₃₆ represents a linear or branched chain (with or without cyclic moieties) of 36 carbon atoms;

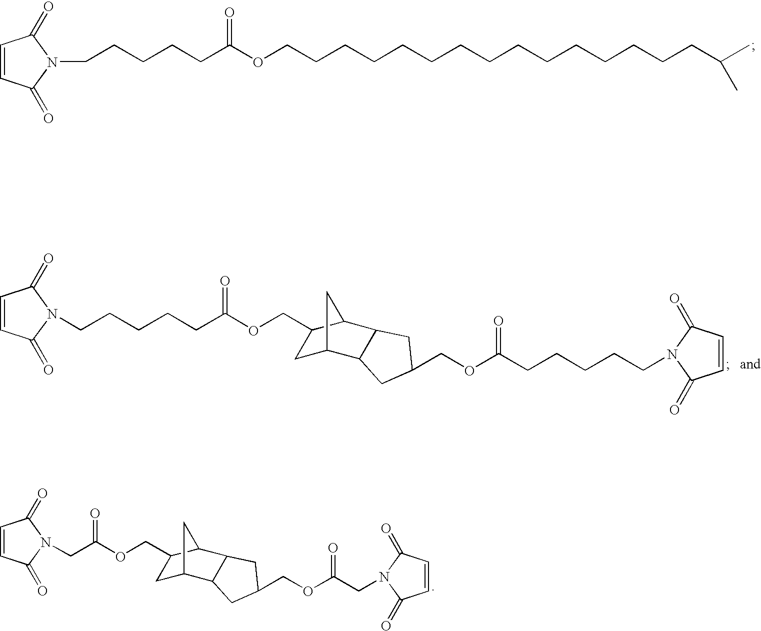

In one embodiment the curable resin of the composition is an acrylate resin. Suitable acrylate resins include those having the generic structure

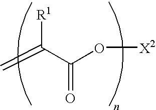

in which n is 1 to 6, R¹ is —H or —CH₃. and X² is an aromatic or aliphatic group. Exemplary X² entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. Commercially available materials include butyl (meth)acrylate, isobutyl (meth)acrylate, tricyclodecanedimethanol diacrylate, 2-ethyl hexyl (meth)acrylate, isodecyl (meth)acrylate, n-lauryl (meth)acrylate, alkyl (meth)acrylate, tridecyl (meth)acrylate, n-stearyl (meth)acrylate, cyclohexyl(meth)acrylate, tetrahydrofurfuryl(meth)acrylate, 2-phenoxy ethyl(meth)acrylate, isobornyl(meth)acrylate, 1,4-butanediol di(meth)acrylate, 1.6 hexanediol di(meth)acrylate, 1,9-nonandiol di(meth)acrylate, perfluorooctylethyl(meth)acrylate, 1,10 decandiol di(meth)acrylate, nonylphenol polypropoxylate (meth)acrylate, and polypentoxylate tetrahydrofurfuryl acrylate, available from Kyoeisha Chemical Co., LTD; polybutadiene urethane dimethacrylate (CN302, NTX6513) and polybutadiene dimethacrylate (CN301, NTX6039, PRO6270) available from Sartomer Company, Inc; polycarbonate urethane diacrylate (ArtResin UN9200A) available from Negami Chemical Industries Co., LTD; acrylated aliphatic urethane oligomers (Ebecryl 230, 264, 265, 270, 284, 4830, 4833, 4834, 4835, 4866, 4881, 4883, 8402, 8800-20R, 8803, 8804) available from Radcure Specialities, Inc; polyester acrylate oligomers (Ebecryl 657, 770, 810, 830, 1657, 1810, 1830) available from Radcure Specialities, Inc.; and epoxy acrylate resins (CN104, 111, 112, 115, 116, 117, 118, 119, 120, 124, 136) available from Sartomer Company, Inc. In one embodiment the acrylate resins are selected from the group consisting of isobornyl acrylate, isobornyl methacrylate, lauryl acrylate, lauryl methacrylate, poly(butadiene) with acrylate functionality and poly(butadiene) with methacrylate functionality.

In one embodiment the curable resin of the composition is a vinyl ether resin. Suitable vinyl ether resins include those having the generic structure

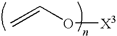

in which n is 1 to 6 and X³ is an aromatic or aliphatic group. Exemplary X³ entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. Commercially available curable resins include cyclohenanedimethanol divinylether, dodecylvinylether, cyclohexyl vinylether, 2-ethylhexyl vinylether, dipropyleneglycol divinylether, hexanediol divinylether, octadecylvinylether, and butandiol divinylether available from International Speciality Products (ISP); Vectomer 4010, 4020, 4030, 4040, 4051, 4210, 4220, 4230, 4060, 5015 available from Sigma-Aldrich, Inc.

In one embodiment the curable resin of the composition is an epoxy. Suitable epoxy resins include bisphenol, naphthalene, and aliphatic type epoxies. Commercially available materials include bisphenol type epoxy resins (Epiclon 830LVP, 830CRP, 835LV, 850CRP) available from Dainippon Ink & Chemicals, Inc.; naphthalene type epoxy (Epiclon HP4032) available from Dainippon Ink & Chemicals, Inc.; aliphatic epoxy resins (Araldite CY179, 184, 192, 175, 179) available from Ciba Specialty Chemicals, (Epoxy 1234, 249, 206) available from Union Carbide Corporation, and (EHPE-3150) available from Daicel Chemical Industries, Ltd. Other suitable epoxy resins include cycloaliphatic epoxy resins, bisphenol-A type epoxy resins, bisphenol-F type epoxy resins, epoxy novolac resins, biphenyl type epoxy resins, naphthalene type epoxy resins, dicyclopentadiene-phenol type epoxy resins, cresol novolac epoxy resins, reactive epoxy diluents, and mixtures thereof.

In another embodiment the curable resin of the composition is a siliconized olefin resin. Suitable siliconized olefin resins are obtained by the selective hydrosilation reaction of silicone and divinyl materials, having the generic structure,

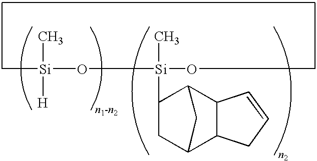

in which n₁ is 2 or more, n₂ is 1 or more and n₁>n₂. These materials are commercially available and can be obtained, for example, from National Starch and Chemical Company.

In another embodiment the curable resin of the composition is a silicone resin. Suitable silicone resins include reactive silicone resins having the generic structure

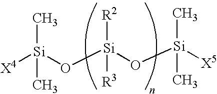

in which n is 0 or any integer, X⁴ and X⁵ are hydrogen, methyl, amine, epoxy, carboxyl, hydroxy, acrylate, methacrylate, mercapto, phenol, or vinyl functional groups, R² and R³ can be —H, —CH₃, vinyl, phenyl, or any hydrocarbon structure with more than two carbons. Commercially available materials include KF8012, KF8002, KF8003, KF-1001, X-22-3710, KF6001, X-22-164C, KF2001, X-22-170DX, X-22-173DX, X-22-174DX X-22-176DX, KF-857, KF862, KF8001, X-22-3367, and X-22-3939A available from Shin-Etsu Silicone International Trading (Shanghai) Co., Ltd.

In another embodiment the curable resin of the composition is a styrene resin. Suitable styrene resins include those resins having the generic structure

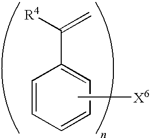

in which n is 1 or greater, R⁴ is —H or —CH₃, and X⁶ is an aliphatic group. Exemplary X⁶ entities include poly(butadienes), poly(carbonates), poly(urethanes), poly(ethers), poly(esters), simple hydrocarbons, and simple hydrocarbons containing functionalities such as carbonyl, carboxyl, amide, carbamate, urea, or ether. These resins are commercially available and can be obtained, for example, from National Starch and Chemical Company or Sigma-Aldrich Co.

In another embodiment the curable resin of the composition is a cyanate ester. Suitable cyanate ester resins include those having the generic structure

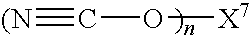

in which n is 1 or larger, and X⁷ is a hydrocarbon group. Exemplary X⁷ entities include bisphenol, phenol or cresol novolac, dicyclopentadiene, polybutadiene, polycarbonate, polyurethane, polyether, or polyester. Commercially available materials include; AroCy L-10, AroCy XU366, AroCy XU371, AroCy XU378, XU71787.02L, and XU 71787.07L, available from Huntsman LLC; Primaset PT30, Primaset PT30 S75, Primaset PT60, Primaset PT60S, Primaset BADCY, Primaset DA230S, Primaset MethylCy, and Primaset LECY, available from Lonza Group Limited; 2-allyphenol cyanate ester, 4-methoxyphenol cyanate ester, 2,2-bis(4-cyanatophenol)-1,1,1,3,3,3-hexafluoropropane, bisphenol A cyanate ester, diallylbisphenol A cyanate ester, 4-phenylphenol cyanate ester, 1,1,1-tris(4-cyanatophenyl)ethane, 4-cumylphenol cyanate ester, 1,1-bis(4-cyanateophenyl)ethane, 2,2,3,4,4,5,5,6,6,7,7-dodecafluorooctanediol dicyanate ester, and 4,4′-bisphenol cyanate ester, available from Oakwood Products, Inc.

The composition further includes a toughening polymer. The toughening polymer serves as a toughening agent and provides green strength to the composition. Green strength, as used herein, refers to the adhesive and cohesive strength of the material before it is cured. The toughening polymer may be curable or non-curable, and may be any known to those in the art to impart toughening properties. Examples of suitable toughening polymers include thermoplastic rubbers, poly(butadiene) polymers, rubber polymers, elastomers, or combinations of these.

Thermoplastic rubbers such as carboxy terminated butadiene-nitrile (CTBN) rubber, carboxy terminated butadiene-nitrile (CTBN)/epoxy adduct, acrylate rubber, vinyl-terminated butadiene rubber, and nitrile butadiene rubber (NBR) are particularly suited for use as the toughening polymer. In one embodiment the toughening polymer is a CTBN epoxy adduct consisting of about 20-80 wt % CTBN and about 20-80 wt % diglycidyl ether bisphenol A: bisphenol A epoxy (DGEBA). A variety of CTBN materials are available from Noveon Inc., and a variety of bisphenol A epoxy materials are available from Dainippon Ink and Chemicals, Inc., and Shell Chemicals. NBR rubbers are commercially available from Zeon Corporation.

In one embodiment the toughening polymer is a poly(butadiene) polymer. Suitable poly(butadiene) polymers include poly(butadienes), epoxidized poly(butadienes), maleic poly(butadienes), acrylated poly(butadienes), butadiene-styrene copolymers, nitrile-butadiene rubber (NBR), and butadiene-crylonitrile copolymers such as carboxyl terminated butadiene-acrylonitrile (CTBN) rubber. Commercially available materials include homopolymer butadiene (Ricon 130, 131, 134, 142, 150, 152, 153, 154, 156, 157, P30D) available from Sartomer Company, Inc; random copolymer of butadiene and styrene (Ricon 100, 181, 184) available from Sartomer Company Inc.; maleinized poly(butadiene) (Ricon 130MA8, 130MA13, 130MA20, 131MA5, 131MA10, 131MA17, 131MA20, 156MA17) available from Sartomer Company, Inc.; acrylated poly(butadienes) (CN302, NTX6513, CN301, NTX6039, PRO6270, Ricacryl 3100, Ricacryl 3500) available from Sartomer Inc.; epoxydized poly(butadienes) (Polybd 600, 605) available from Sartomer Company. Inc. and Epolead PB3600 available from Daicel Chemical Industries, Ltd; and acrylonitrile and butadiene copolymers (Hycar CTBN series, ATBN series, VTBN series and ETBN series) available from Hanse Chemical.

Other suitable materials for the toughening polymer of the composition include rubber polymers such as block copolymers of monovinyl aromatic hydrocarbons and conjugated diene, e.g., styrene-butadiene, styrene-butadiene-styrene (SBS), styrene-isoprene-styrene (SIS), styrene-ethylene-butylene-styrene (SEBS), and styrene-ethylene-propylene-styrene (SEPS).

Other suitable materials for use as the toughening polymer of the composition include ethylene-vinyl acetate polymers, other ethylene esters and copolymers, e.g., ethylene methacrylate, ethylene n-butyl acrylate and ethylene acrylic acid; polyvinyl acetate and random copolymers thereof; polyacrylates; polyamides; polyesters; and polyvinyl alcohols and copolymers thereof.

Suitable materials for use as the toughening polymer of the composition further include polyamide, phenoxy, polybenzoxazine, polyether sulfone, polyimide, benzoxazine, vinyl ether, polybenzoxyzole, polyester, polystyrene, polycarbonate, poly(vinyl chloride), polyisobutylene, polyacrylonitrile, poly(methyl methacrylate), poly(vinyl acetate), poly(2-vinylpridine), cis-1,4-polyisoprene, 3,4-polychloroprene, vinyl copolymer, poly(ethylene oxide), poly(ethylene glycol), polyformaldehyde, polyacetaldehyde, poly(b-propiolacetone), poly(10-decanoate), poly(ethylene terephthalate), polycaprolactam, poly(11-undecanoamide), poly(m-phenylene-terephthalamide), poly(tetramethlyene-m-benzenesulfonamide), polyester polyarylate, poly(phenylene oxide), poly(phenylene sulfide), polysulfone, polyimide, polyetheretherketone, polyetherimide, fluorinated polyimide, polyimide siloxane, poly-iosindolo-quinazolinedione, polythioetherimide poly-phenyl-quinoxaline, polyquinixalone, imide-aryl ether phenylquinoxaline copolymer, polyquinoxaline, polybenzimidazole, polybenzoxazole, polynorbornene, poly(arylene ethers), polysilane, parylene, benzocyclobutenes, hydroxy(benzoxazole) copolymer, poly(silarylene siloxanes), and polybenzimidazole.

In one embodiment the toughening polymer of the composition is a polymer comprising a backbone and pendant from the backbone at least one siloxane moiety, and at least one reactive moiety capable of reacting to form a new covalent bond. Examples of suitable siloxanes include elastomeric polymers prepared from: 3-(tris-(trimethylsilyloxy)silyl)-propyl methacrylate, n-butyl acrylate, glycidyl methacrylate, acrylonitrile, and cyanoethyl acrylate; 3-(tris(trimethylsilyloxy)silyl)-propyl methacrylate, n-butyl acrylate, glycidyl methacrylate, and acrylonitrile; and 3-(tris(trimethylsilyloxy)silyl)-propyl methacrylate, n-butyl acrylate, glycidyl methacrylate, and cyanoethyl acrylate.

If curing agent is required for the curable resin and/or toughening polymer of the composition, its selection is dependent on the curable resin(s) and/or toughening polymer(s) used and the processing conditions employed. The curing agent for the curable resin and/or toughening polymer systems will be present in an effective amount, typically up to 60 wt % of the composition before B-staging, excluding solvent content. If curing agent is required for both the curable resin and the toughening polymer those curing agents may be the same or they may be different from one another. As curing agents, the composition may use aromatic amines, alycyclic amines, aliphatic amines, tertiary phosphines, triazines, metal salts, aromatic hydroxyl compounds, or a combination of these. Examples of such catalysts include imidazoles, such as 2-methylimidazole, 2-undecylimidazole, 2-heptadecyl imidazole, 2-phenylimidazole, 2-ethyl 4-methylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition product of an imidazole and trimellitic acid; tertiary amines, such as N,N-dimethyl benzylamine, N,N-dimethylaniline, N,N-dimethyltoluidine, N,N-dimethyl-p-anisidine, p-halogeno-N,N-dimethylaniline, 2-N-ethylanilino ethanol, tri-n-butylamine, pyridine, quinoline, N-methylmorpholine, triethanolamine, triethylenediamine, N,N,N′,N′-tetramethylbutanediamine, N-methylpiperidine; phenols, such as phenol, cresol, xylenol, resorcine, and phloroglucin; organic metal salts, such as lead naphthenate, lead stearate, zinc naphthenate, zinc octolate, tin oleate, dibutyl tin maleate, manganese naphthenate, cobalt naphthenate, and acetyl aceton iron; and inorganic metal salts, such as stannic chloride, zinc chloride and aluminum chloride; peroxides, such as benzoyl peroxide, lauroyl peroxide, octanoyl peroxide, acetyl peroxide, para-chlorobenzoyl peroxide and di-t-butyl diperphthalate; acid anhydrides, such as carboxylic acid anhydride, maleic anhydride, phthalic anhydride, lauric anhydride, pyromellitic anhydride, trimellitic anhydride, hexahydrophthalic anhydride; hexahydropyromellitic anhydride and hexahydrotrimellitic anhydride, azo compounds, such as azoisobutylonitrile, 2,2′-azobispropane, m,m′-azoxystyrene, hydrozones, and mixtures thereof.

In another embodiment, the curing agent for the curable resin and/or toughening polymer is a cure accelerator and may be selected from the group consisting of triphenylphosphine, alkyl-substituted imidazoles, imidazolium salts, onium salts, quartenary phosphonium compounds, onium borates, metal chelates, 1,8-diazacyclo[5.4.0]undex-7-ene or a mixture thereof.

In another embodiment the curing agent for the curable resin and/or toughening polymer can be either a free radical initiator or an ionic initiator, depending on whether a radical or ionic curing curable resin and/or toughening polymer is chosen. If a free radical initiator is used, it will be present in an effective amount. An effective amount typically is 0.1 to 10 wt % of the adhesive composition before B-staging, excluding solvent content. Free-radical initiators include peroxides, such as butyl peroctoates and dicumyl peroxide, and azo compounds, such as 2,2′-azobis(2-methyl-propanenitrile) and 2,2′-azobis(2-methyl-butanenitrile).

If an ionic initiator is used, it will be present in an effective amount. An effective amount typically is 0.1 to 10 wt % of the composition before B-staging, excluding solvent content. Suitable ionic curing agents include dicyandiamide, adipic dihydrazide, BF₃-amine complexes, amine salts and modified imidazole compounds.

Metal compounds also can be employed as cure accelerators for cyanate ester resin systems and include, but are not limited to, metal napthenates, metal acetylacetonates (chelates), metal octoates, metal acetates, metal halides, metal imidazole complexes, and metal amine complexes.

Other cure accelerators that may be included for the curable resin and/or toughening polymer of the composition include triphenylphosphine, alkyl-substituted imidazoles, imidazolium salts, and onium borates.

In some cases, it may be desirable to use more than one type of cure for the composition. For example, both ionic and free radical initiation may be desirable, in which case both free radical cure and ionic cure resins and/or toughening polymers can be used in the composition. These compositions would contain effective amounts of initiators for each type of curable resin and/or toughening polymer. Such a composition would permit, for example, the curing process to be started by ionic initiation using UV irradiation, and in a later processing step, to be completed by free radical initiation upon the application of heat.

One or more fillers may be included in the composition and may be added to adjust numerous properties including rheology, stress, coefficient of thermal expansion, electrical and/or thermal conductivity, and modulus. The particular type of filler is not critical to the present invention and can be selected by one skilled in the art to suit the needs of the specific end use. Fillers may be conductive or nonconductive. Examples of suitable conductive fillers include carbon black, graphite, gold, silver, copper, platinum, palladium, nickel, aluminum, silicon carbide, boron nitride, diamond, and alumina. Examples of suitable nonconductive fillers include alumina, aluminum hydroxide, silica, vermiculite, mica, wollastonite, calcium carbonate, titania, sand, glass, barium sulfate, zirconium, carbon black, organic fillers, and halogenated ethylene polymers, such as, tetrafluoroethylene, trifluoroethylene, vinylidene fluoride, vinyl fluoride, vinylidene chloride, and vinyl chloride. The filler particles may be of any appropriate size ranging from nano size to several mils. The choice of such size for any particular package configuration is within the expertise of one skilled in the art. Filler may be present in an amount from 0 to 95 wt % of the composition before B-staging, excluding solvent content.

In one embodiment, a coupling agent, or adhesion promoter, may be added to the composition. Adhesion promoter selection will depend on the application requirements and curable resin chemistry employed. Adhesion promoters, if used, will be used in an effective amount, typically up to 5 wt % of the composition before B-staging, excluding solvent content. Examples of suitable adhesion promoters include: epoxy-type silane coupling agent, amine-type silane coupling agent, mercapto-type silane coupling agent; Z6040 epoxy silane, Z6030 methacryloxypropyltrimethoxy-silane or Z6020 amine silane available from Dow Corning; A186 Silane, A187 Silane, A174 Silane, or A1289 available from OSI Silquest; Organosilane SI264 available from Degussa; Johoku Chemical CBT-1 Carbobenzotriazole available from Johoku Chemical; functional benzotriazoles; thiazoles; titanates; and zirconates.

In a further embodiment, a surfactant may be added to the composition. Suitable surfactants include silicones, polyethylene glycol, polyoxyethylene/-polyoxypropylene block copolymers, ethylene diamine based polyoxyethylene/-polyoxypropylene block copolymers, polyol-based polyoxyalkylenes, fatty alcohol-based polyoxyalkylenes, and fatty alcohol polyoxyalkylene alkyl ethers. Surfactants, if used, will be used in an effective amount: a typical effective amount is an amount up to 5 wt % of the composition before B-staging, excluding solvent content.

In another embodiment a wetting agent may be included in the composition. Wetting agent selection will depend on the application requirements and the curable resin chemistry utilized. Wetting agents, if used, will be used in an effective amount: a typical effective amount is up to 5 wt % of the composition before B-staging, excluding solvent content. Examples of suitable wetting agents include Fluorad FC-4430 Fluorosurfactant available from 3M, Clariant Fluowet OTN, BYK W-990, Surfynol 104 Surfactant, Crompton Silwet L-7280, Triton X100 available from Rhom and Haas, Propylene glycol with a preferable Mw greater than 240, Gama-Butyrolactone, castor oil, glycerin or other fatty acids, and silanes.

In a further embodiment, a flow control agent may be included in the composition. Flow control agent selection will depend on the application requirements and curable resin chemistry employed. Flow control agents, if used, will be present in an effective amount: an effective amount is an amount up to 20 wt % of the composition before B-staging, excluding solvent content. Examples of suitable flow control agents include Cab-O-Sil TS720 available from Cabot, Aerosil R202 or R972 available from Degussa, fumed silicas, fumed aluminas, or fumed metal oxides.

In a further embodiment, an air release agent (defoamer) may be added to the composition. Air release agent selection will depend on the application requirements and curable resin chemistry employed. Air release agents, if used, will be used in an effective amount. A typical effective amount will be up to 5 wt % of the composition before B-staging, excluding solvent content. Examples of suitable air release agents include Antifoam 1400 available from Dow Corning, DuPont Modoflow, and BYK A-510.

In some embodiments these compositions are formulated with tackifying resins in order to improve adhesion and introduce tack; examples of tackifying resins include naturally-occurring resins and modified naturally-occurring resins; polyterpene resins; phenolic modified terpene resins; coumarons-indene resins; aliphatic and aromatic petroleum hydrocarbon resins; phthalate esters; hydrogenated hydrocarbons, hydrogenated rosins and hydrogenated rosin esters. Tackifying resins, if used, will be used in an effective amount. A typical effective amount will be up to 5 wt % of the composition before B-staging, excluding solvent content.

In some embodiments other components may be included in the composition, for example, diluents such as liquid polybutene or polypropylene; petroleum waxes such as paraffin and microcrystalline waxes, polyethylene greases, hydrogenated animal, fish and vegetable fats, mineral oil and synthetic waxes, naphthenic or paraffinic mineral oils.

Other additives, such as stabilizers, antioxidants, impact modifiers, and colorants, in types and amounts known in the art, may also be added to the composition.

Common solvents with a proper boiling point ranging from 25° C. to 230° C. may be added to the composition. Examples of suitable solvents that may be utilized include ketones, esters, alcohols, ethers, and other common solvents that are stable and dissolve the curable resins in the composition. Suitable solvents include γ-butyrolactone, propylene glycol methyl ethyl acetate (PGMEA), methyl ethyl ketone (MEK), toluene, ethyl acetate, and 4-methyl-2-pentanone.

The carrier of this invention may be anything to which the composition will be applied in a thin layer, and that will hold the composition during B-staging into a film. The carrier also may hold the film through application to an item to be bonded and/or additional processing steps, such as lamination to a wafer or to a dicing tape. One particularly suitable carrier is a release liner. Examples of suitable release liners include polyimide (PI) film, polyethylenenapthalate (PEN) film, and polyethyleneterephthalate (PET) film.

The composition is coated on to the carrier, forming a thin, uniform layer. The composition is then B-staged to create a non-tacky, uniform layer of adhesive film. In one embodiment of the invention the adhesive is hardened to a non-tacky state so that the film may be stored and/or sent to a separate location before the film is applied to a substrate, die, or wafer. The hardening of the adhesive may be accomplished in numerous ways, depending on the adhesive formulation employed.

In one embodiment the composition comprises at least a liquid curable resin and a solvent. In this embodiment the adhesive is hardened to a non-tacky, or very low-flow, state by heating the composition sufficiently to evaporate the solvent and partially cure the curable resin or resins.

In another embodiment the composition contains a solid curable resin dissolved in a solvent. In this embodiment the adhesive is hardened to a non-tacky, or very low flow, state by heating the composition sufficiently to evaporate the solvent, leaving a non-tacky resin-based film.

In another embodiment the composition contains at least one liquid curable resin. In this embodiment the composition is hardened to a non-tacky, or very low flow, state by heating the adhesive sufficiently to partially advance the curable resin to a non-tacky, or very low flow, state.

One skilled in the art would appreciate that the composition might also contain a combination of curable resins and toughening polymers that could be dried, B-staged, and cured with a combination of mechanisms. For instance, the formulation might be B-staged through the use of ultraviolet radiation and, in a downstream manufacturing step after die attach, cured through the use of heat. The formulation might also contain a combination of curable resins and/or toughening polymers that have two separate cure temperatures such that the adhesive could be hardened by heating the composition at the first (and lower) temperature, causing the first curable resin or toughening polymer to cure and the overall adhesive formulation to harden to a non-tacky state. In this case the second curable resin or toughening polymer, which has a second, and higher, curing temperature would be cured in a subsequent processing step after the die is attached.

The B-staging temperature will generally be within a range of 60° C. to 200° C., and B-staging will be effected within a time period ranging from one minute to two hours, depending on the particular curable resin formulation chosen. The time and temperature B-staging profile for each composition will vary, and different compositions can be designed to provide the B-staging profile that will be suited to the particular industrial manufacturing process.

The film adhesive of the present invention may be used to bond any two adherends together and is especially well-suited to bond a semiconductor die to a substrate with low voids during subsequent thermal processing, such as curing and wirebonding operations. The semiconductor die may be any type, size, or shape, as it is not critical to the present invention. The bondline (thickness of adhesive after cure) of the assembly may be any thickness suitable for the specific semiconductor package and typically will range between 5 and 150 μm.

The substrate to which the die is bonded may be any required for the particular package, including but not limited to organic, glass, metallic, and ceramic. The low-voiding behavior is particularly advantageous in applications utilizing organic substrates, as they tend to be the most susceptible to void formation during packaging operations due to their tendency to absorb moisture at room temperature and release that moisture during thermal operations. Examples of suitable organic substrates include rigid or semi-rigid substrates, primarily made of a conventional resin materials including but not limited to bismaleimide triazine (BT) resin, epoxy resin, and FR-4 board.

The low voiding behavior is observed during thermal processing of the die/film/substrate assembly. Thermal processing may include cure and wirebonding operations. Whereas non-inventive films tend to develop voids in the bondline, the films of this invention, which include the void reduction compound, are less prone to develop significant voids during downstream thermal operations.

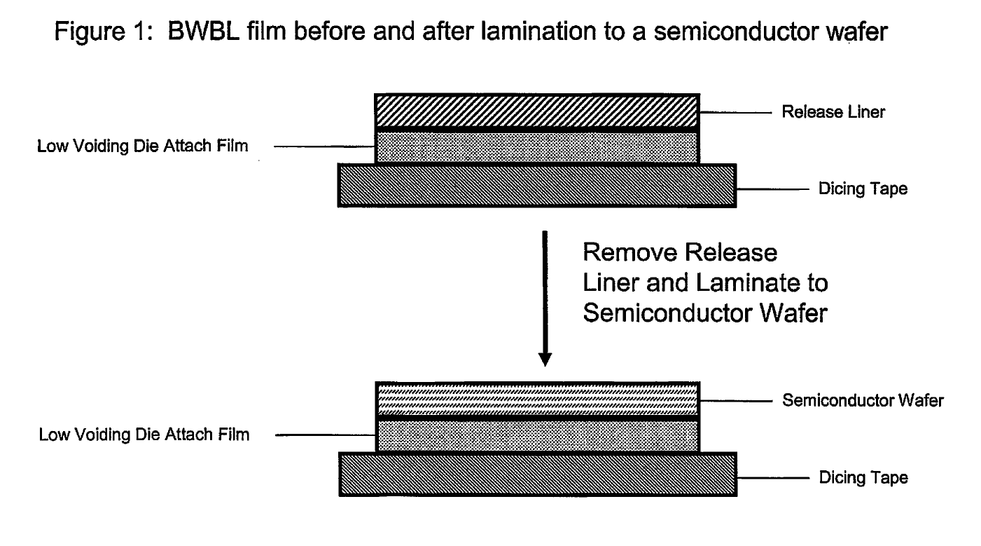

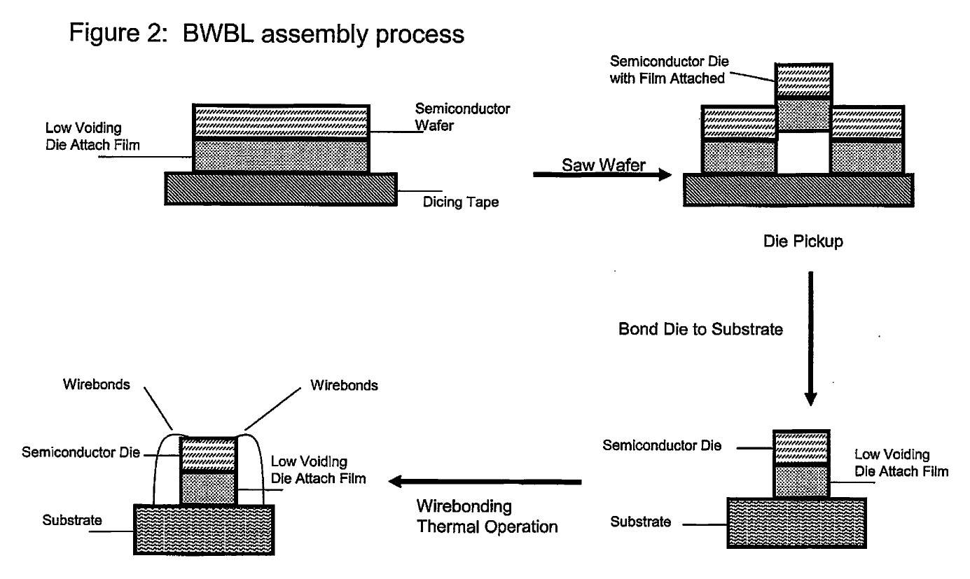

This method of reducing voids is particularly useful in bundled wafer backside lamination (BWBL) processes. In this process the adhesive film produced according to the method of this invention is laminated to a dicing tape to form a BWBL film. The release liner is removed from the adhesive side of the BWBL and the adhesive side contacted to a semiconductor wafer. The BWBL film is then laminated to the semiconductor wafer, resulting in the adhesive film being sandwiched between the dicing tape and the semiconductor wafer. A schematic representation of BWBL film before and after lamination to a semiconductor wafer is presented in FIG. 1. The wafer is then diced into individual dies, to which the adhesive film remains attached. The dicing tape serves as a support structure during the dicing operation. The individual dies are subsequently removed from the dicing tape and attached to a substrate, typically using pick-and-place die bonding equipment. During this step the adhesive film releases from the dicing tape and remains adhered to the die. The adhesive side of the film plus die is contacted with the substrate and with heat and/or pressure the adhesive serves to bond the semiconductor die to the substrate. The die/film/substrate assembly is then processed in at least one thermal operation, such as wirebonding, cure, or solder reflow. A schematic representation of one embodiment of this assembly process is presented in FIG. 2. The resulting assembly has fewer voids in the bondline compared to a similar assembly prepared with a non-inventive film, which does not contain a void reduction compound. The presence of the void reduction compound in the film adhesive prevents the formation of substantial voids during thermal processing operations, such as wirebonding and cure.

The dicing tape used in this process may be either a pressure sensitive adhesive (PSA) dicing tape or an ultraviolet (UV)-curable dicing tape. Typical tapes have an adhesive thickness of 3 to 30 μm on a polyolefin or poly vinyl chloride (PVC) carrier film that is 70 to 110 μm thick. One skilled in the art would appreciate that the tapes with different configurations may be selected to suit the particular industrial process to be utilized.

The cure may be accomplished either as an individual process step, or in conjunction with another processing operation such as solder reflow or wire bonding. Cure conditions may be selected by the practitioner without undue experimentation, as appropriate for the specific curable resin and toughening polymer chemistry utilized in the composition. In one embodiment the film is cured at temperatures ranging from 80° to 200° C. for 1 to 5 hours.

The film of this invention demonstrates very good wet-out on the substrate. This property promotes the utility of the film as an adhesive, and is typically observed by the amount of voiding present in the bondline immediately after die attach. Voiding of less than 5% of the surface area of the die is considered good wet-out performance. One key predictor of the wet-out performance of a film is its melt viscosity at die attach temperature. In one embodiment the melt viscosity of the low voiding film is between 500 and 10,000 poise in the 100° to 150° C. temperature range.

### EXAMPLES

For each of the examples contained herein, samples were prepared and evaluated according to the following procedure. A void reduction compound, and curing agent for that compound, was added to and mixed with various formulations as specified in each example. The resulting composition was then coated onto a silicone coated polyester release liner. The composition on the release liner was then B-staged at 100° C. for three minutes so that the composition was converted to a film with final thickness of about 20 μm. Next, the exposed side of the film was laminated to a dicing tape at room temperature. The release liner was then removed from the film and the film/dicing tape structure was laminated to a glass wafer so that the film was disposed between, and adhered to both, the dicing tape and the wafer. Next, the wafer was diced into individual 10 mm×10 mm die. Dies plus adhesive were removed from the dicing tape, that is, the adhesive film released from the dicing tape and remained adhered to the glass die. Next, the die, with film attached, was contacted to a BT substrate at 120° C. and five kg force for five seconds so that voiding behavior of the film in the bondline could be readily observed after various thermal operations. The samples were then subjected to thermal conditions simulating a variety of cure and wirebonding operations that might be experienced by a semiconductor package after die attach. The bondline of each sample was examined visually through the glass die and percent voiding was estimated for each immediately after die attach, to assess wet-out performance, and also after each thermal operation. The percent voiding of the inventive samples after various thermal processes was compared to the percent voiding of the comparative samples to determine the efficacy of the void reduction compound in each case.

### Example 1

### Void Reduction Compounds in CTBN Toughening Polymer/Epoxy Curable Resin System

A variety of void reduction compounds were tested in a system based on CTBN and epoxy. The void reduction compounds tested are listed in Table 1, below.

TABLE 1
VOID REDUCTION COMPOUNDS TESTED IN CTBN TOUGHENING POLYMER/EPOXY
CURABLE RESIN SYSTEM

| | | |
|---|---|---|
| VRC- 1 | methacryloxypropyltris(trim ethyl-siloxy) silane | 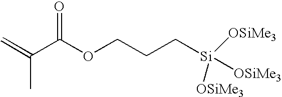 |
| VRC- 2 | vinyl terminated polydimethylsiloxane, reduced volatility, 5,000cP | 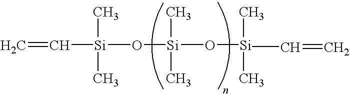 |
| VRC- 3 | vinyl terminated (15-17% diphenylsiloxane)-dimethyl- siloxane copolymer, 10,000cP | 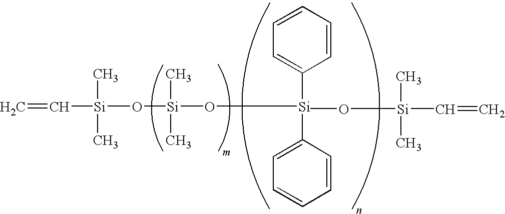 |
| VRC- 4 | Epoxypropoxypropyl terminated polydimethyl- siloxane, 100-140cP | 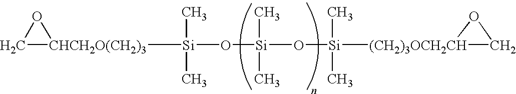 |
| VRC- 5 | Epoxypropoxypropyl terminated polydimethylsiloxane, 20- 35cP | 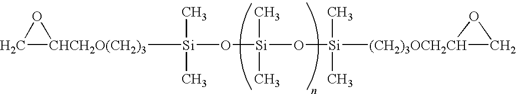 |
| VRC- 6 | (0.8-1.2% vinylmethylsiloxane)- dimethylsiloxane copolymer, trimethylsiloxy terminated, 800-1,200cP | 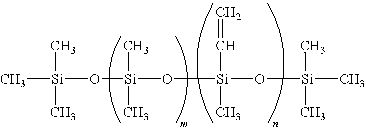 |

The formulations based on CTBN and epoxy were prepared with the compositions presented in Table 2, below. Comp A is comparative example A; Inv B to H are the inventive examples B to H. VRC is void reduction compound. The compositions as reported do not include solvent. Approximately 50% methyl ethyl ketone (MEK) solvent was added to facilitate coating in making the test samples.

TABLE 2
FORMULATIONS FOR FILMS BASED ON CTBN TOUGHENING
POLYMER/EPOXY CURABLE RESIN SYSTEM IN WEIGHT PERCENT

| Components | Comp A | Inv B | Inv C | Inv D | Inv E | Inv F | Inv G | Inv H |
|---|---|---|---|---|---|---|---|---|
| CTBN toughening | 65 | 60 | 64 | 64 | 64 | 64 | 65 | 65 |
| polymer | | | | | | | | |
| Cresol novalac | 25 | 26 | 22 | 22 | 22 | 22 | 22 | 22 |
| epoxy curable | | | | | | | | |
| resin | | | | | | | | |
| Aromatic diamine | 5 | 5 | 5 | 5 | 5 | 5 | 5 | 5 |
| hardener | | | | | | | | |
| Amine catalyst, | 0.5 | 0.5 | 0.5 | 0.5 | 0.5 | 0.5 | 0.5 | 0.5 |
| wt % | | | | | | | | |
| Silane adhesion | 1.5 | 1 | 1 | 1 | 1 | 1 | 1 | 1 |
| promoter | | | | | | | | |
| Fumed silica filler | 3 | 2 | 2 | 2 | 2 | 2 | 2 | 2 |
| Peroxide curing | 0 | 1 | 1 | 1 | 1 | 1 | 0 | 0 |
| agent | | | | | | | | |
| VRC-1 | 0 | 4.5 | 4.5 | 0 | 0 | 0 | 0 | 0 |
| VRC-2 | 0 | 0 | 0 | 4.5 | 0 | 0 | 0 | 0 |
| VRC-3 | 0 | 0 | 0 | 0 | 4.5 | 0 | 0 | 0 |
| VRC-4 | 0 | 0 | 0 | 0 | 0 | 0 | 4.5 | 0 |
| VRC-5 | 0 | 0 | 0 | 0 | 0 | 0 | 0 | 4.5 |
| VRC-6 | 0 | 0 | 0 | 0 | 0 | 4.5 | 0 | 0 |

Voiding data for these formulations, after being subjected to time and temperature conditions to simulate die attach, cure, and wire bonding thermal operations, are presented in Table 3 below. In all cases, the wirebonding simulation was performed at 175° C. for 10 minutes. Those combinations that were not evaluated are shown as “N/A”.

TABLE 3
PERCENT VOIDING FOR FILMS PREPARED FROM CTBN
TOUGHENING POLYMER/EPOXY CURABLE RESIN SYSTEM

| Thermal conditions | | | | | | | | | |
|---|---|---|---|---|---|---|---|---|---|
| and operation | | Cmp A | Inv B | Inv C | Inv D | Inv E | Inv F | Inv G | Inv H |
| 1 hr at 120° C. | die attach | <5% | N/A | N/A | N/A | N/A | N/A | N/A | N/A |
| | cure | <5% | <5% | <5% | N/A | N/A | N/A | N/A | N/A |
| | wire bond | 80% | <5% | <5% | N/A | N/A | N/A | N/A | N/A |
| 2 hr at 120° C. | die attach | <5% | <5% | <5% | N/A | N/A | N/A | N/A | N/A |
| | cure | <5% | <5% | <5% | N/A | N/A | N/A | N/A | N/A |
| | wire bond | <5% | <5% | <5% | N/A | N/A | N/A | N/A | N/A |
| 30 min at 100° | die attach | <5% | <5% | <5% | N/A | N/A | N/A | N/A | N/A |
| C. + 30 min | cure | 80% | <5% | <5% | N/A | N/A | N/A | N/A | N/A |
| at 150° C. | wire bond | 80% | <5% | <5% | N/A | N/A | N/A | N/A | N/A |
| 30 min at 100° | die attach | <5% | <5% | <5% | <5% | <5% | <5% | <5% | <5% |
| C. + 30 min | cure | <5% | <5% | <5% | <5% | 10% | <5% | <5% | <5% |
| at 125° C. | wire bond | 30% | <5% | <5% | <5% | 10% | <5% | <5% | <5% |
| 30 min at 120° | die attach | <5% | <5% | <5% | N/A | N/A | N/A | N/A | N/A |
| C. + 30 min | cure | 80% | <5% | <5% | N/A | N/A | N/A | N/A | N/A |
| at 150° C. | wire bond | 80% | <5% | <5% | N/A | N/A | N/A | N/A | N/A |
| None | die attach | <5% | <5% | <5% | N/A | N/A | N/A | N/A | N/A |
| | cure | N/A | N/A | N/A | N/A | N/A | N/A | N/A | N/A |
| | wire bond | 80% | 30% | 30% | N/A | N/A | N/A | N/A | N/A |

With nearly all cure profiles tested the comparative film had high voiding (30-80%) after cure and/or wirebonding. In contrast, all of the inventive films had low voiding (5-10%) after these thermal operations. The exception to this was seen with the two hour at 120° C. cure profile, where even the comparative example had very low voiding after die attach, cure, and wirebonding simulation. This is because the very long cure time at a low temperature enables the moisture in the substrate to dissipate without causing voids as severely as is seen with shorter profiles at higher temperatures. However, since such a long cure time is detrimental to production rates, this approach would be undesirable in an industrial setting.

### Example 2

### Void Reduction Compound in Siloxane Toughening Polymer/Epoxy Curable Resin System

A void reduction compound was tested in a system based on epoxy resin and an epoxy-siloxane acrylic toughening polymer. A similar comparative film containing no void reduction compound was also prepared and tested. The void reduction compound tested in this example was methacryloxypropyltris (trimethylsiloxy) silane (denoted VRC-1 in Example 1).

The formulations based on the epoxy-siloxane acrylic toughening polymer and epoxy resin were prepared with the compositions presented in Table 4, below. These compositions are non-inclusive of solvent. Approximately 50% methyl ethyl ketone (MEK) solvent was added to facilitate coating to prepare the test samples.

TABLE 4
FORMULATIONS FOR FILMS BASED ON SILOXANE
TOUGHENING POLYMER/EPOXY CURABLE RESIN
SYSTEM IN WEIGHT PERCENT

| | Comp I | Inv J |
|---|---|---|
| Siloxane toughening polymer | 65 | 60 |
| Cresol novalac epoxy curable resin | 25 | 23 |
| Aromatic diamine hardener | 5 | 5 |
| Amine catalyst | 0.5 | 0.5 |
| Silane adhesion promoter | 1.5 | 1 |
| Fumed silica filler | 3 | 2 |
| Peroxide curing agent | 0 | 2.5 |
| VRC-1 | 0 | 6 |

Voiding data for these formulations, after die attach (D/A), cure simulation (30 min at 100° C.+30 min at 125° C.) and wirebonding simulation (10 min at 175° C.) are presented in Table 5 below.

TABLE 5
PERCENT VOIDING FOR FILMS PREPARED FROM SILOXANE
TOUGHENING POLYMER/EPOXY CURABLE RESIN SYSTEM

| | | |
|---|---|---|
| Thermal Conditions | | |
| and Operation | Comp I | Inv J |

| | | | |
|---|---|---|---|
| 30 min at 100 C. + | die attach | <5% | <5% |
| 30 min at 125 C. | cure | <5% | <5% |
| | wire bond | 30% | <5% |

In this example the film containing void reduction compound had fewer voids after wirebonding than the comparative film that did not contain void reduction compound.

### Example 3

### Void Reduction Compound in CTBN Toughening Polymer/Bismaleimide Curable Resin System

A void reduction compound was tested in a system based on bismaleimide curable resin and a CTBN toughening polymer. The void reduction compound tested in this example was methacryloxypropyl t-structure siloxane, 10-20 cP, which will be referenced as VRC-7, and has the following structure:

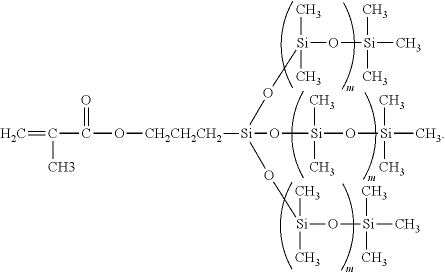

The formulation based on CTBN and bismaleimide was prepared with the composition presented in Table 6, below. This composition is non-inclusive of solvent. Approximately 50% methyl ethyl ketone (MEK) solvent was added to facilitate coating to prepare the test samples.

TABLE 6
FORMULATION FOR FILMS BASED ON CTBN
TOUGHENING POLYMER/BISMALEIMIDE
CURABLE RESIN SYSTEM IN WEIGHT PERCENT

| | Inv K |
|---|---|
| CTBN toughening polymer | 76 |
| Bismaleimide curable resin | 16 |
| Silane adhesion promoter | 1 |
| Fumed silica filler | 2 |
| Peroxide curing agent | 2 |
| VRC-7 | 3 |

Voiding data for this formulation, after die attach (D/A), cure simulation (30 min at 100° C.+30 min at 125° C.) and wirebonding simulation (10 min at 175° C.) are presented in Table 7 below.

TABLE 7
PERCENT VOIDS FOR FILMS PREPARED FROM
CTBN TOUGHENING POLYMER/BISMALEIMIDE
CURABLE RESIN SYSTEM

| Thermal Conditions | | |
|---|---|---|
| and Operation | | Inv K |
| 30 min at | die attach | <5% |
| 100° C. + | cure | <5% |
| 30 min at | wire bond | <5% |
| 125° C. | | |

In this example the film containing void reduction compound had negligible voids after die attach, cure, and wirebonding simulation.

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

What is claimed:

1. An adhesive film prepared from a composition comprising: (i) a toughening polymer; (ii) a curable resin; (iii) a curing agent for the curable resin; (iv) a void reduction compound having at least two Si—O moieties contiguous with each other and at least one reactive functionality; and (v) a curing agent for the void reduction compound.

2. The adhesive film of claim 1 wherein the reactive functionality is selected from the group consisting of vinyl, hydroxyl, carboxyl, epoxy, acrylate, methacrylate, and a combination of these.

3. The adhesive film of claim 1 wherein the curable resin is selected from the group consisting of bismaleimide and epoxy.

4. The adhesive film of claim 1 wherein the toughening polymer is selected from the group consisting of CTBN rubber and a polymer comprising a backbone and pendant from the backbone at least one siloxane moiety and at least one reactive moiety capable of reacting to form a new covalent bond.

5. The adhesive of claim 1 wherein the void reduction compound is selected from the group consisting of: 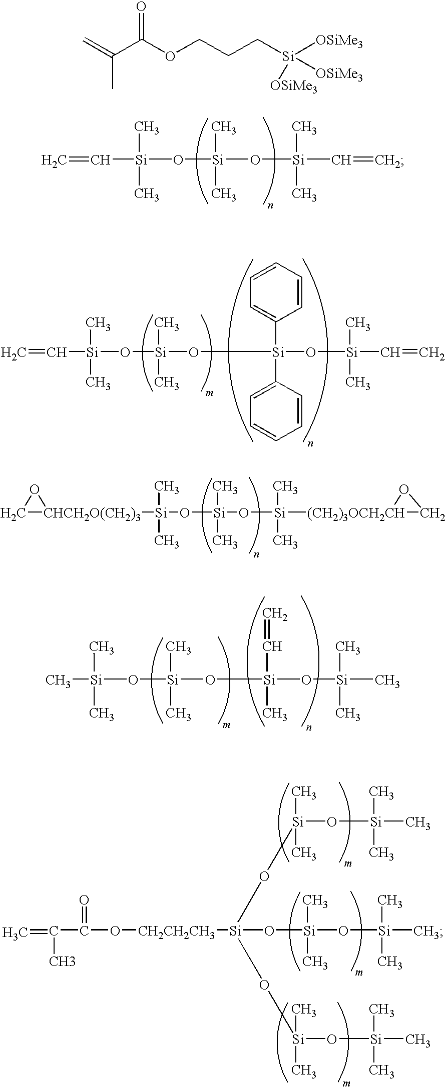
and combinations of these.

6. A method for reducing voids in an adhesive used in a semiconductor package comprising
(i) providing a composition comprising a toughening polymer, a curable resin, a curing agent for the curable resin, a void reduction compound having at least two Si—O moieties contiguous with each other and at least one reactive functionality, and a curing agent for the void reduction compound;
(ii) applying the composition to a carrier;
(iii) B-staging the composition thereby producing an adhesive film plus carrier;
(iv) contacting the adhesive side of the adhesive film plus carrier to a semiconductor die or to a substrate for the semiconductor die;
(v) removing the carrier to expose the adhesive film;
(vi) contacting the semiconductor die, if the adhesive is applied to the substrate for the semiconductor die, or contacting the substrate, if the adhesive is applied to the semiconductor die, to the exposed adhesive film so that the adhesive film is disposed between the die and its substrate; and
(vii) subjecting the adhesive film to at least one thermal operation.

7. The method of claim 6 wherein the reactive functionality is selected from the group consisting of vinyl, hydroxyl, carboxyl, epoxy, acrylate, methacrylate, and a combination of these.

8. The method of claim 6 wherein the curable resin is selected from the group consisting of bismaleimide and epoxy.

9. The method of claim 6 wherein the toughening polymer is selected from the group consisting of CTBN rubber and a polymer comprising a backbone and pendant from the backbone at least one siloxane moiety and at least one reactive moiety capable of reacting to form a new covalent bond.

10. The method of claim 6 wherein the void reduction compound is selected from the group consisting of: 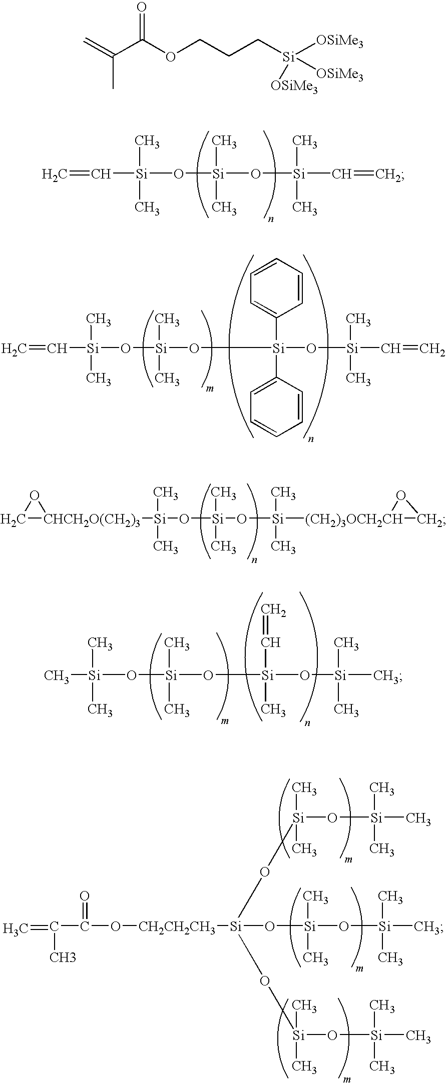
and combinations of these.

11. The method of claim 6 wherein the carrier is a release liner selected from the group consisting of polyimide film, polyethylenenapthalate film, and polyethyleneterephthalate film.

12. The method of claim 6 wherein the substrate is an organic substrate for semiconductor packaging selected from the group consisting of bismaleimide triazine resin, epoxy resin, and FR-4 board.

13. The method of claim 6 wherein the thermal operation is selected from the group consisting of curing of the adhesive or wirebonding of the package.

14. A semiconductor package prepared by
(i) providing a composition comprising a toughening polymer, a curable resin, a curing agent for the curable resin, a void reduction compound having at least two Si—O moieties contiguous with each other and at least one reactive functionality, and a curing agent for the void reduction compound;
(ii) applying the composition to a carrier;
(iii) B-staging the composition, thereby producing an adhesive film plus carrier;
(iv) contacting the adhesive side of the adhesive film plus carrier to a dicing tape;
(v) laminating the adhesive film to the dicing tape, thereby producing a bundled wafer backside lamination (BWBL) film;
(vi) removing the carrier, contacting the exposed adhesive side of the BWBL film to a semiconductor wafer and laminating the BWBL to the semiconductor wafer so that the adhesive film is disposed between the semiconductor wafer and the dicing tape;
(vii) dicing the wafer and adhesive into individual semiconductor dies with adhesive;
(viii) removing a die with the adhesive film attached from the dicing tape;
(ix) contacting the adhesive film to a substrate so that the adhesive film is disposed between the semiconductor die and the substrate to form an assembly; and
(x) subjecting the assembly to at least one thermal operation.

15. The semiconductor package of claim 14 wherein the reactive functionality is selected from the group consisting of vinyl, hydroxyl, carboxyl, epoxy, acrylate, methacrylate, and a combination of these.

16. The semiconductor package of claim 14 wherein the curable resin is selected from the group consisting of bismaleimide and epoxy.

17. The semiconductor package of claim 14 wherein the toughening polymer is selected from the group consisting of CTBN rubber and a polymer comprising a backbone and pendant from the backbone at least one siloxane moiety and at least one reactive moiety capable of reacting to form a new covalent bond.

18. The semiconductor package of claim 14 wherein the void reduction compound is selected from the group consisting of: 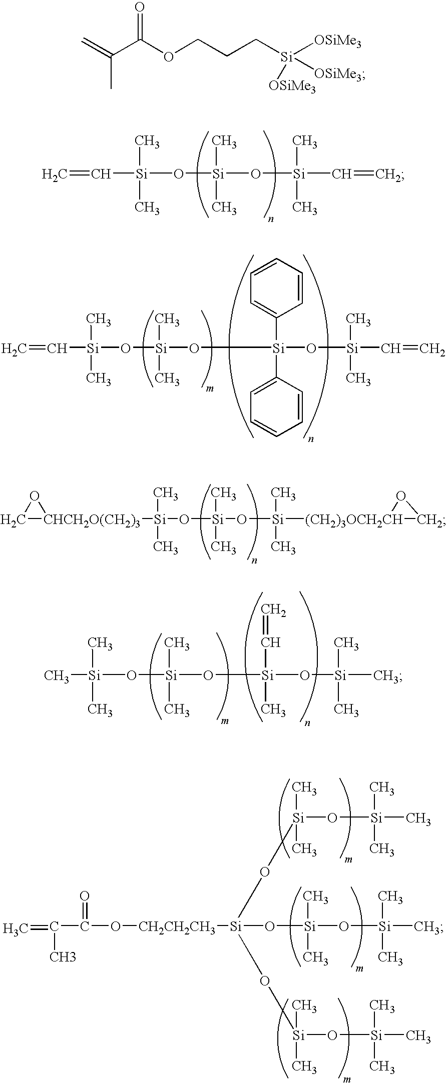
and combinations of these.

19. The semiconductor package of claim 14 wherein the substrate is an organic substrate for semiconductor packaging selected from the group consisting of bismaleimide triazine resin, epoxy resin, and FR-4 board.

20. The semiconductor package of claim 14 wherein the thermal operation is selected from the group consisting of curing the adhesive and wirebonding the package.
